(19) United States
(12) Patent Application Publication
(10) Pub. No.: US 2021/0072312 A1
(43) Pub. Date: Mar. 11, 2021

(54) Boundary Scan Test System And Method Thereof

(71) Applicants: Inventec (Pudong) Technology Corporation, Shanghai (CN); Inventec Corporation, Taipei City (TW)

(72) Inventor: Chang-Qing Mu, Shanghai (CN)

(21) Appl. No.: 16/576,120

(22) Filed: Sep. 19, 2019

(30) Foreign Application Priority Data
Sep. 9, 2019 (CN) 201910865863.8

(51) Int. Cl. G01R 31/3177; G06F 13/40

(52) U.S. Cl. CPC G01R 31/3177; G06F 13/4027

(57) ABSTRACT

A boundary scan test system and a method thereof are disclosed. In the boundary scan test system, two ends of a first loopback line of each CPU test card are connected to another CPU test card and a boundary scan unit of a DIMM test card, respectively, and two ends of a second loopback line of each CPU test card are connected to boundary scan units of the different DIMM test cards, respectively, so as to generate boundary scan nets. A test control host executes a diagnosis program to select and trigger one of the boundary scan units of each boundary scan net, to output an excitation signal, and make the other boundary scan units receive corresponding response signals, and compare the response signals and corresponding expectation signals in each boundary scan net, so as to output a diagnosis result of each boundary scan net.

### CROSS-REFERENCE TO RELATED APPLICATION

This application claims the benefit of Chinese Application Serial No. 201910865863.8 filed Sep. 9, 2019, which is hereby incorporated herein by reference in its entirety.

### BACKGROUND OF THE INVENTION

### 1. Field of the Invention

The present invention relates to a test system and a method thereof, and more particularly to a boundary scan test system and a method thereof.

### 2. Description of the Related Art

On the server motherboard production line, an original central processing unit (CPU) of the server motherboard is used for boundary scan test, and each time a server motherboard is tested, the CPU must be plugged and unplugged once. Therefore, a large number of tests may damage the CPU, and it causes the CPU become a test consumable product; however, the original CPU of the motherboard is expensive, so it causes a problem of too high test cost for the production line.

For this reason, the relevant manufacturers developed CPU test cards according to the actual needs of the production line. A size of the CPU test card must be the same as that of the original CPU, so design of the CPU test card faces a challenge of how to configure test resources for thousands of to-be-tested pins under the size of the original CPU.

In recent years, commercially available CPU test cards generally adopt multi-plate design, each test card covers only a part of pins of the CPU slot, so that the test cards need to be replaced for testing plate by plate during the test process, and test results of multiple CPU test cards are integrated to generate a test report. However, this test manner has the problems of high time cost, complex test fixture design, and complex test flow control caused by frequent replacement of test cards, and this test manner is not applicable to the production line.

Therefore, according to the actual needs of the production line, how to design a CPU test card which has a low cost and can assist the boundary scan test process on a production line, and how to design a better boundary scan test process corresponding to the CPU test card, are key issues in the industry.

### SUMMARY OF THE INVENTION

An objective of the present invention is to provide a boundary scan test system and a method thereof, to solve the conventional problems.

In order to achieve the objective, the present invention provides a boundary scan test system applied to perform a boundary scan test on a to-be-tested motherboard. The to-be-tested motherboard includes a plurality of CPU slots and a plurality of dual in-line memory modules (DIMM) slots, the plurality of CPU slots are connected to each other via a plurality of quick path interconnect (QPI) lines, and the plurality of CPU slots are connected to the plurality of DIMM slots via a plurality of input/output (I/O) lines. The boundary scan test system includes a plurality of CPU test cards, a plurality of DIMM test cards and a test control host. The plurality of CPU test cards are plugged into the plurality of CPU slots in one-to-one correspondence, and each of the plurality of CPU test card includes a plurality of first loopback lines and a plurality of second loopback lines. Two ends of each first loopback line of each CPU test card are connected to one of the QPI lines and one of the I/O lines, respectively, and two ends of each second loopback line of each CPU test card are connected to two of the I/O lines, respectively. The plurality of DIMM test cards are plugged into the plurality of DIMM slots in one-to-one correspondence. Each DIMM test card includes at least one boundary scan unit connected to one of the I/O lines. The test control host is configured to generate a plurality of boundary scan nets according to connection relationships between the plurality of CPU test cards, the plurality of DIMM test cards and the to-be-tested motherboard, and execute a diagnosis program to select and trigger one of the boundary scan units in each boundary scan net, to output an excitation signal, and make the other boundary scan units receive response signals, and then the test control host compares each response signal and its corresponding expectation signal in each boundary scan net, to output a diagnosis result of each boundary scan net.

Furthermore, the present invention discloses a boundary scan test method including following steps: providing a to-be-tested motherboard, a plurality of CPU test cards, and a plurality of DIMM test cards, wherein the to-be-tested motherboard includes a plurality of CPU slots and a plurality of DIMM slots, the plurality of CPU slots are connected to each other via a plurality of QPI lines, the plurality of CPU slots are connected to the plurality of DIMM slots via a plurality of I/O lines, each CPU test card includes a plurality of first loopback lines and a plurality of second loopback lines, and each DIMM test card includes at least one boundary scan unit; plugging the plurality of CPU test cards into the plurality of CPU slots in one-to-one correspondence, and connecting two ends of each first loopback line of each CPU test card to one of the plurality of QPI lines and one of the plurality of I/O lines, respectively, and connecting two ends of each second loopback line of each CPU test card to two of the plurality of I/O lines, respectively; plugging the plurality of DIMM test cards into the plurality of DIMM slots in one-to-one correspondence, to connect the at least one boundary scan unit of each DIMM test card to one of the plurality of I/O lines; generating a plurality of boundary scan nets according to connection relationships between the plurality of CPU test cards, the plurality of DIMM test cards and the to-be-tested motherboard; in each boundary scan net, selecting and triggering one of the boundary scan units to output an excitation signal, and making the other boundary scan units receive response signals corresponding thereto; and comparing each of the response signals with its corresponding expectation signal in each boundary scan net, to output a diagnosis result of each boundary scan net.

According to the above-mentioned contents, the difference between the system and method of the present invention and the conventional technology is that, in the present invention, two ends of the first loopback line of each CPU test card are connected to another CPU test card and a boundary scan unit of one of the DIMM test cards, respectively, two ends of the second loopback line of each CPU test card are connected to the boundary scan units of the different DIMM test cards, respectively, so as to generate the plurality of boundary scan nets, and the test control host can execute the diagnosis program to select and trigger one of the boundary scan units in each boundary scan net, to output the excitation signal, and make the other boundary scan units receive the response signals corresponding thereto, respectively, and the test control host can compare each of the response signals and its expectation signal in each boundary scan net, to output the diagnosis result of each boundary scan net.

By the aforementioned technical solution, the CPU test card of the present invention can basically cover the to-be-tested pins of the original CPU, so that the required test resources can be reduced maximally, and it is not necessary to frequently change the CPU test card during the boundary scan test process, thereby providing a clear and convenient diagnosis process, and accurately covering all faulty pins.

### BRIEF DESCRIPTION OF THE DRAWINGS

The structure, operating principle and effects of the present invention will be described in detail by way of various embodiments which are illustrated in the accompanying drawings.

FIG. 1 is a schematic structural view of an embodiment of a boundary scan test system of the present invention.

FIG. 2 is a flowchart of an embodiment of a boundary scan test method performed by the boundary scan test system of FIG. 1 according to the present invention.

### DETAILED DESCRIPTION OF THE PREFERRED EMBODIMENTS

The following embodiments of the present invention are herein described in detail with reference to the accompanying drawings. These drawings show specific examples of the embodiments of the present invention. These embodiments are provided so that this disclosure will be thorough and complete, and will fully convey the scope of the invention to those skilled in the art. It is to be acknowledged that these embodiments are exemplary implementations and are not to be construed as limiting the scope of the present invention in any way. Further modifications to the disclosed embodiments, as well as other embodiments, are also included within the scope of the appended claims. These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts.

It is to be acknowledged that, although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and all combinations of one or more of the associated listed items.

It will be acknowledged that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

In addition, unless explicitly described to the contrary, the word “comprise” and variations such as “comprises” or “comprising”, will be acknowledged to imply the inclusion of stated elements but not the exclusion of any other elements.

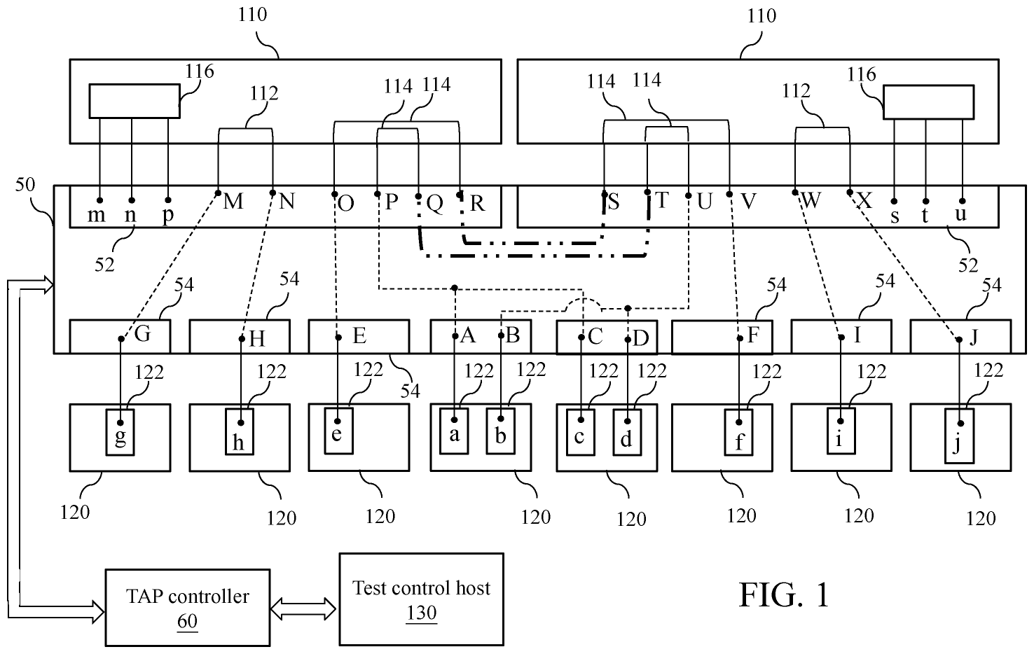

Please refer to FIG. 1, which is a schematic structural view of an embodiment of a boundary scan test system of the present invention. In this embodiment, the boundary scan test system can perform a boundary scan test on a to-be-tested motherboard 50. The to-be-tested motherboard 50 comprises a plurality of CPU slots 52 and a plurality of DIMM slots 54, and the CPU slots 52 are connected to each other via a plurality of QPI lines, and the CPU slots 52 are connected to the DIMM slots 54 via a plurality of I/O lines. In order to prevent complex illustration, in this embodiment, two CPU slots 52, eight DIMM slots 54, ten I/O lines (shown by dashed lines), and two QPI lines (shown by bold chain lines) are shown in FIG. 1 for illustration; however, the present invention is not limited to this embodiment, the amounts of the above-mentioned components can be adjusted according to the actual condition.

The boundary scan test system can comprise a plurality of CPU test cards 110, a plurality of DIMM test cards 120, a test access port (TAP) controller 60, and a test control host 130. The CPU test cards 110 are plugged into the CPU slots 52 in one-to-one correspondence (the plugging relationships between the CPU test cards 110 and the CPU slots 52 are shown by connection lines in FIG. 1). The DIMM test cards 120 are plugged into the DIMM slots 54 in one-to-one correspondence (the plugging relationships between the DIMM test cards 120 and the DIMM slots 54 are shown by connection lines in FIG. 1). In this embodiment, there are two CPU test cards 110 and eight DIMM test cards 120. The test control host 130 can be connected, via the TAP controller 60 and the to-be-tested motherboard 50, to the CPU test cards 110 plugged into the CPU slots 52 and the DIMM test cards 120 plugged into the DIMM slots 54, so as to transmit information and data to perform the boundary scan test. It should be noted that a size of each CPU test card 110 must be the same as that of an original CPU, and a size of each DIMM test card 110 must be the same as that of an original DIMM.

Each CPU test card 110 can comprise a plurality of first loopback lines 114 and a plurality of second loopback lines 112. When each CPU test card 110 is plugged into the CPU slot 52 corresponding thereto, two ends of each first loopback line 114 of each CPU test card 110 can be connected to one of the QPI lines and one of the I/O lines, respectively, and two ends of each second loopback line 112 of each CPU test card 110 can be connected to two of the I/O lines, respectively. Each DIMM test card 120 can comprise at least one boundary scan unit 122, and when each DIMM test card 120 is plugged into the DIMM slot 54 corresponding thereto, the at least one boundary scan unit 122 of each DIMM test card 120 is connected to one of the I/O lines. In order to prevent complex illustration, in this embodiment, each CPU test card 110 comprises one second loopback line 112 and two first loopback lines 114, each of the six DIMM test cards 120 can comprise one boundary scan unit 122, and each of the two DIMM test cards 120 can comprise two boundary scan units 122; however, the present invention is not limited to this embodiment, and the amounts of above-mentioned components can be adjusted according to the actual condition. Each boundary scan unit 122 can be used as an activation terminal or a response terminal.

The test control host 130 can generate a plurality of boundary scan nets according to connection relationships between the CPU test cards 110, the DIMM test cards 120 and the to-be-tested motherboard 50. Each boundary scan net can comprise a plurality of test path pins through which the boundary scan paths of the boundary scan net pass. The test path pins can include connection pins of the CPU slot 52 for connecting to the DIMM slots (that is, the pins connecting the CPU slots 52 and the I/O lines), the I/O pins of the DIMM slots 54 for connecting to the CPU slots 52 (that is, the pins connecting the DIMM slots 54 and the I/O lines).

In this embodiment, there are four boundary scan nets; the boundary scan path of the first boundary scan net can start from the terminal g (that is, the boundary scan unit 122) to the terminal h (that is, another boundary scan unit 122) via the pin G, (that is, the pin connecting the DIMM slot 54 and the I/O line), the pin M, (that is, the pin connecting the CPU slot 52 and the I/O line), the second loopback line 112, the pin N (that is, the pin connecting the CPU slot 52 and the I/O line), and the pin H (that is, the pin connecting the DIMM slot 54 and the I/O line). Therefore, the test path pins comprised in the first boundary scan net are the pin G, the pin M, the pin N and the pin H. The boundary scan path of the second boundary scan net can start from the terminal e (that is, the boundary scan unit 122) to the terminal f (that is, another boundary scan unit 122) via the pin E (that is, the pin connecting the DIMM slot 54 and the I/O line), the pin O (that is, the pin connecting the CPU slot 52 and the I/O line), the first first-loopback line 114, the pin R (that is, the pin connecting the CPU slot 52 and another CPU slot 52), the QPI line, the pin S (that is, the pin connecting the CPU slot 52 and another CPU slot 52), the second first-loopback line 114, the pin V (that is, the pin connecting the CPU slot 52 and the I/O line), and the pin F (that is, the pin connecting the DIMM slot 54 and the I/O line). The test path pins comprised in the second boundary scan net are the pin E, the pin O, the pin R, the pin S, the pin V and the pin F. The boundary scan path of the third boundary scan net can start from the terminal a (that is, the boundary scan unit 122), and after passing through the pin A (that is, the pin connecting the DIMM slot 54 and the I/O line), the boundary scan path of the third boundary scan net is divided into two sub-paths, the first sub-path passes through the pin C (that is, the pin connecting the DIMM slot 54 and the I/O line) and then enters the terminal c (that is, the boundary scan unit 122); the second sub-path passes through the pin P (that is, the pin connecting the CPU slot 52 and the I/O line), the first first-loopback line 114, the pin Q (that is, the pin connecting the CPU slot 52 and another CPU slot 52), the QPI line, the pin T (that is, the pin connecting the CPU slot 52 and another CPU slot 52), the second first-loopback line 114, and the pin U (that is, the pin connecting the CPU slot 52 and the I/O line). After passing through the pin U, the second sub-path is branched, and the first branch passes through the pin D (that is, the pin connecting the DIMM slot 54 and the I/O line) and then enters the terminal d (that is, the boundary scan unit 122), and the second branch passes through the pin B (that is, the pin connecting the DIMM slot 54 and the I/O line) and then enters the terminal b (the boundary scan unit 122). The test path pins comprised in the third boundary scan net are the pin A, the pin P, the pin Q, the pin T, the pin U, the pin D, the pin B and the pin C. The boundary scan path of the fourth boundary scan net can start from the terminal i (that is, a boundary scan unit 122) to the terminal j (that is, another boundary scan unit 122), via the pin I (that is, the pin connecting the DIMM slot 54 and the I/O line), the pin W (that is, the pin connecting the CPU slot 52 and the I/O line), the second loopback line 112, the pin X (that is, the pin connecting the CPU slot 52 and the I/O line), and the pin J (that is, the pin connecting the DIMM slot 54 and the I/O line). The test path pins comprised in the fourth boundary scan net are the pin I, the pin W, the pin X and the pin J.

The test control host 130 can execute the diagnosis program on each boundary scan net, to select and trigger one of the boundary scan units 122 of each boundary scan net, to output an excitation signal, and make the other boundary scan units 122 receive the response signals, and the test control host 130 can compare each of the response signals with its corresponding expectation signal in each boundary scan net, to output the diagnosis result of each boundary scan net. In other words, the test control host 130 can perform the boundary scan test according to the boundary scan paths of each boundary scan net, and when one of the boundary scan units 122 of each boundary scan net is selected as the activation terminal to output the excitation signal, it can expect, based on the boundary scan paths, the corresponding expectation signals received by other boundary scan units 122 (that is, the response terminals) of the boundary scan net. When the response signal received by one of the boundary scan unit 122 mismatches its corresponding expectation signal which is expected to receive, it indicates the boundary scan net has a faulty pin, so the test control host 130 needs to further perform a faulty diagnosis according to the test result of each boundary scan net (that is, the test result is the response signal of each boundary scan net), so as to output the diagnosis result of each boundary scan net. The diagnosis result can indicate whether the test path pins of each boundary scan net are normally soldered with the motherboard, and indicate whether there is a faulty condition such as open-circuit fault or short-circuit fault.

The rules of the faulty diagnosis, according to the test result of each boundary scan net, includes three rules. In the first rule, when only one of the response signals of a certain boundary scan net mismatches its expectation signal, the test control host 130 reports an error in the test path pin which is connected to the boundary scan unit receiving the response signal mismatching its expectation signal. In the second rule, when all of the response signals of a certain boundary scan net mismatch their corresponding expectation signals, the test control host 130 reports errors of all test path pins of the certain boundary scan net. In the third rule, when multiple test paths of a certain boundary scan net pass a certain test path pin, the test control host 130 checks whether the test paths via the certain test path pin pass the test, and when at least one of the test paths via the certain test path pin passes the test, the test control host 130 indicates that the certain test path pin passes the test, and when all of the test paths via the certain test path pin fail to pass the test, the test control host 130 reports an error of the certain test path pin.

The third boundary scan net of this embodiment is taken as an example for illustration. When the terminal a is selected as the activation terminal to output the excitation signal, if only the response signal received by the terminal b, serving as the response terminal, mismatches its corresponding expectation signal, the test control host 130 reports an error of the test path pin (that is, the pin B) connected to the terminal b, and at this time, the response signal received by the terminal d, serving as the response terminal, matches its corresponding expectation signal, so the test control host 130 does not report an error of the test path pins A, P, Q, T and U shared by the terminal b and the terminal d. When only the response signal received by the terminal c, serving as the response terminal, mismatches its corresponding expectation signal, the test control host 130 reports an error of the test path pin (that is, the pin C) connected to the terminal c. When only the response signal received by the terminal d, serving as the response terminal, mismatches its expectation signal, the test control host 130 reports an error of the test path pin (that is, the pin D) connected to the terminal d. When the response signals, received by the terminal b and the terminal c serving as the response terminals, mismatches their expectation signals, the test control host 130 reports errors in the test path pins (that is, the pins B and C) connected to the terminal b and the terminal c. When the response signals received by the terminal c and the terminal d, serving as the response terminals, mismatches their corresponding expectation signals, the test control host 130 reports errors of the test path pins (that is, pins C and D) connected to the terminal c and the terminal d. When the response signals received by the terminal b and the terminal d, serving as the response terminals, mismatches their corresponding expectation signals, there are test path pins A, P, Q, T and U shared by the terminal b and the terminal d, so the test control host 130 reports errors of the test path pins (that is, the pins B and D) connected to the terminal b and the terminal d, and also needs to report errors of the shared test path pins A, P, Q, T, and U. When the response signals received by all terminals (that is, the terminals b, c and d), serving as the response terminals, mismatches their corresponding expectation signals, the test control host 130 reports errors of all test path pins (that is, the pins A, B, C, D, P, Q, T and U) comprised in the boundary scan net. Therefore, the test control host 130 can perform the faulty diagnosis according to the test result of the third boundary scan net, to output the diagnosis result of the boundary scan net.

Furthermore, in this embodiment, each CPU test card 110 can include the at least one boundary scan chip 116 disposed thereon, and when each CPU test card 110 is plugged into the CPU slot 52 corresponding thereto, the at least one boundary scan chip 116 can be connected to a plurality of ground pins, a plurality of power pins and a plurality of control I/O pins of the CPU slot 52. It should be noted that, in order to prevent complex illustration, in this embodiment, each CPU test card 110 includes only one boundary scan chip 116 disposed thereon, and each boundary scan chip 116 is connected to a ground pin (that is, the pin m or the pin s), a power supply pin (that is, the pin n or the pin t), and a control I/O pin (that is, the pin p or the pin u); however, the present invention is not limited to this embodiment.

In this embodiment, the test control host 130 can be connected to the CPU test cards 110 plugged into the CPU slots 52, via the TAP controller 60 and the to-be-tested motherboard 50, and transmit information and data to each other, so as to perform the boundary scan test on the ground pins, the power pins and the control I/O pins.

With the configuration of the first loopback line and the second loopback line of each CPU test card 110 of this embodiment, each CPU test card 110 can cover all QPI pins (that is, the pins connecting the CPU slot 52 and the QPI lines) of each CPU slot 52, and the connection pins (that is, the pins connecting the CPU slot 52 and the I/O line) between each CPU slot 52 and the DIMM slots. When the test control host 130 performs the boundary scan test on the pins through the TAP controller 60, the CPU test cards 110 do not need to provide boundary scan hardware resources, so as to reduce the test resources required for the original CPU with the original size. Furthermore, with the configuration of the boundary scan chip 116 disposed on each CPU test card 110, each CPU test card 110 can cover a part of the ground pins, the power pins and the control I/O pins of each CPU slot 52, and when the test control host 130 performs the boundary scan test on the pins through the TAP controller 60, the CPU test card 110 is required to provide the boundary scan hardware resources.

Using the CPU test card of the present invention to replace the Haswell CPU manufactured by Intel is taken as an example. The CPU slot corresponding to the Haswell CPU has 3647 pins. With the configuration of the first loopback lines, the second loopback lines and the boundary scan chip, the CPU test card of the present invention can basically cover 166 ground pins, 76 power pins and 297 control I/O pins of the Haswell CPU, and also can cover all QPI pins and all connection pins (916 pins in total) of each CPU slot; as a result, the CPU test card of the present invention can cover and test 40% of all pins of the CPU slot under the size of the original CPU, so as to save test resource maximally. Furthermore, it is not necessary to frequently change the CPU test card during the boundary scan test process, so a clear and convenient diagnosis process can be provided to accurately cover all faulty pins.

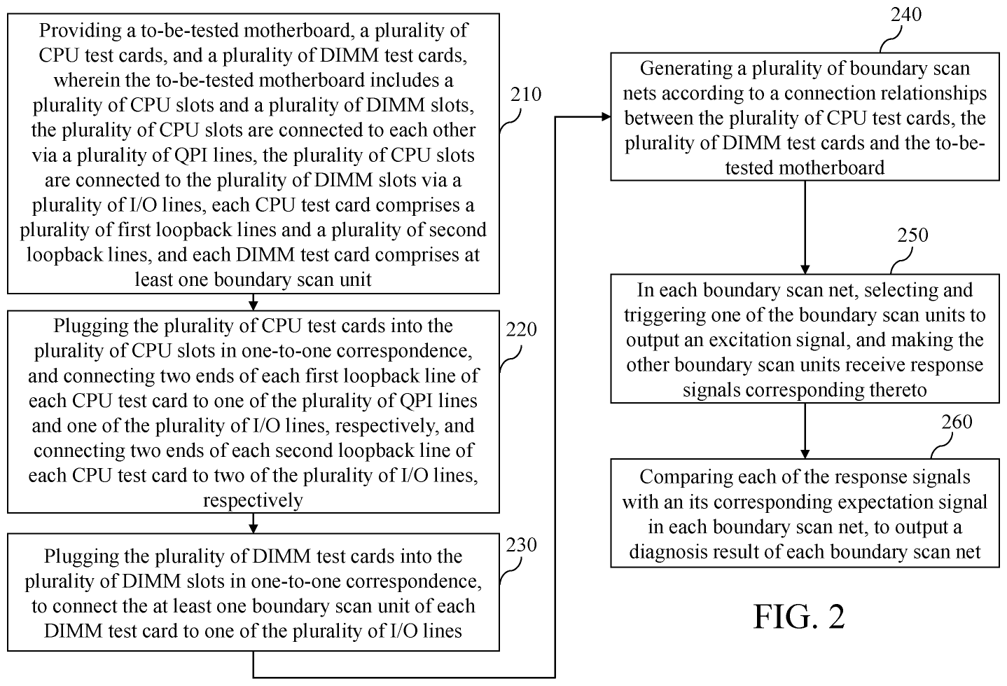

Please refer to FIG. 2, which is a flowchart of an embodiment of a boundary scan test method performed by the boundary scan test system of FIG. 1. In this embodiment, the boundary scan test method includes steps: providing a to-be-tested motherboard, a plurality of CPU test cards, and a plurality of DIMM test cards, wherein the to-be-tested motherboard includes a plurality of CPU slots and a plurality of DIMM slots, the plurality of CPU slots are connected to each other via a plurality of QPI lines, the plurality of CPU slots are connected to the plurality of DIMM slots via a plurality of I/O lines, each CPU test card comprises a plurality of first loopback lines and a plurality of second loopback lines, and each DIMM test card comprises at least one boundary scan unit (step 210); plugging the plurality of CPU test cards into the plurality of CPU slots in one-to-one correspondence, and connecting two ends of each first loopback line of each CPU test card to one of the plurality of QPI lines and one of the plurality of I/O lines, respectively, and connecting two ends of each second loopback line of each CPU test card to two of the plurality of I/O lines, respectively (step 220); plugging the plurality of DIMM test cards into the plurality of DIMM slots in one-to-one correspondence, to connect the at least one boundary scan unit of each DIMM test card to one of the plurality of I/O lines (step 230); generating a plurality of boundary scan nets according to a connection relationships between the plurality of CPU test cards, the plurality of DIMM test cards and the to-be-tested motherboard (step 240); in each boundary scan net, selecting and triggering one of the boundary scan units to output an excitation signal, and making the other boundary scan units receive response signals corresponding thereto (step 250); and comparing each of the response signals with an its corresponding expectation signal in each boundary scan net, to output a diagnosis result of each boundary scan net (step 260).

Through aforementioned steps, two ends of the first loopback line of each CPU test card can be connected to another CPU test card and the boundary scan unit of the DIMM test card, respectively, and two ends of the second loopback line of each CPU test card can be connected to the boundary scan units of the different DIMM test card, respectively, so as to generate the plurality of boundary scan nets, and the test control host can execute the diagnosis program to select and trigger one of the boundary scan units of each boundary scan net, to output the excitation signal, and make the other boundary scan units receive the corresponding response signals, and then compare each of the response signal with its corresponding expectation signal in each boundary scan net, so as to output the diagnosis result of each boundary scan net.

The step that the test control host compares each of the response signals and the corresponding expectation signals in each boundary scan net to output the diagnosis result of each boundary scan net, can comprise sub-steps below. When only one response signal of a certain boundary scan net mismatches its corresponding expectation signal, the test control host reports an error of the test path pin connected to the boundary scan unit receiving the response signal mismatching its corresponding expectation signal, so as to output the diagnosis result of the certain boundary scan net. When all response signals of the certain boundary scan net mismatch their corresponding expectation signals, the test control host reports errors of all test path pins of the certain boundary scan net, so as to output the diagnosis result of the certain boundary scan net. When multiple test paths of a certain boundary scan net pass through a certain test path pin, the test control host checks whether the multiple test paths through the certain test path pin pass the test, and when at least one of the multiple test paths through the certain test path pin passes the test, the test control host indicates that the certain test path pin passes the test, and when all of the multiple test paths through the certain test path pin fail to pass the test, the test control host reports an error of the certain test path pin.

Furthermore, each CPU test card comprises the at least one boundary scan chip disposed thereon, and when each CPU test card is plugged into the CPU slot corresponding thereto, the at least one boundary scan chip can be connected to the ground pins, the power pins and the control I/O pins of the CPU slot, to provide the hardware resource required by the boundary scan test when the test control host uses the TAP controller to perform the boundary scan test on the ground pins, the power pins and the control I/O pins.

According to above-mentioned contents, the difference between the system and method of the present invention and conventional technology is that, in the system and method of the present invention, two ends of the first loopback line of each CPU test card can be connected to another CPU test card and the boundary scan unit of the DIMM test card, respectively, and two ends of the second loopback line of each CPU test card can be connected to the boundary scan units of the different DIMM test card, respectively, and the plurality of boundary scan nets can be generated; the test control host can execute the diagnosis program to select and trigger one of the boundary scan units of each boundary scan net, to output the excitation signal, and make the other boundary scan units receive the corresponding response signals, and the test control host can compare each of the response signals with its corresponding expectation signal in each boundary scan net, to output the diagnosis result of each boundary scan net. By the technical solution, the CPU test card of the present invention can maximally save test resources under the size of the original CPU, and it is not necessary to frequently change the CPU test card during the boundary scan test process, so as to provide a clear and convenient diagnosis process, and accurately cover all faulty pins.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. A boundary scan test system, applied to perform a boundary scan test on a to-be-tested motherboard comprising a plurality of central processing unit (CPU) slots and a plurality of dual in-line memory modules (DIMM) slots, wherein the plurality of CPU slots are connected to each other via a plurality of quick path interconnect (QPI) lines, the plurality of CPU slots are connected to the plurality of DIMM slots via a plurality of input/output (I/O) lines, and the boundary scan test system comprises:
a plurality of CPU test cards plugged into the plurality of CPU slots in one-to-one correspondence, wherein each of the plurality of CPU test cards comprises a plurality of first loopback lines and a plurality of second loopback lines, two ends of each of the plurality of first loopback lines are connected to one of the plurality of QPI lines and one of the plurality of I/O lines, respectively, and two ends of each of the plurality of second loopback lines are connected to two of the plurality of I/O lines, respectively;
a plurality of DIMM test cards plugged into the plurality of DIMM slots in one-to-one correspondence, wherein each of the plurality of DIMM test cards comprises at least one boundary scan unit connected to one of the plurality of I/O lines; and
a test control host configured to generate a plurality of boundary scan nets according to connection relationships between the plurality of CPU test cards, the plurality of DIMM test cards and the to-be-tested motherboard, and execute a diagnosis program to select and trigger one of the plurality of boundary scan units in each of the plurality of boundary scan nets to output an excitation signal, and make other of the plurality of boundary scan units of each of the plurality of boundary scan nets receive response signals, and compare each of the response signals with its corresponding expectation signal in each of the plurality of boundary scan nets, so as to output a diagnosis result of each of the plurality of boundary scan nets.

2. The boundary scan test system according to claim 1, wherein each of the plurality of boundary scan nets comprises a plurality of test path pins, the operation of the test control host to compare each of the response signals and its corresponding expectation signal in each of the plurality of boundary scan nets, to output the diagnosis result of each of the plurality of boundary scan nets, comprises:
when only one response signal mismatches its corresponding expectation signal in a certain boundary scan net of the plurality of boundary scan nets, the test control host reports an error of the test path pin connected to the boundary scan unit receiving the only one response signal mismatching its corresponding expectation signal, and outputs the diagnosis result of the certain boundary scan net;
wherein multiple test paths of a certain boundary scan net of the plurality of boundary scan nets pass a certain test path pin of the plurality of test path pins, the test control host checks whether the multiple test paths through the certain test path pin pass the test, when at least one of the multiple test paths through the certain test path pin passes the test, it indicates that the certain test path pins passes the test, and when all of the multiple test paths through the certain test path pins fail to pass the test, the test control host reports an error of the certain test path pin.

3. The boundary scan test system according to claim 1, wherein each of the plurality of boundary scan nets comprises a plurality of test path pins, and the operation of the test control host to compare each of the response signals and its corresponding expectation signal in each of the plurality of boundary scan nets, to output the diagnosis result of each of the plurality of boundary scan nets, comprises:
when all of the response signals of a certain boundary scan net of the plurality of boundary scan nets mismatch their corresponding expectation signals, the test control host reports errors of all of the plurality of test path pins of the certain boundary scan net, and outputs the diagnosis result of the certain boundary scan net;
wherein multiple test paths of a certain boundary scan net of the plurality of boundary scan nets pass a certain test path pin of the plurality of test path pins, the test control host checks whether the multiple test paths through the certain test path pin pass the test, and when at least one of the multiple test paths through the certain test path pin passes the test, it indicates that the certain test path pin passes the test, and when all of the multiple test paths through the certain test path pin fail to pass the test, the test control host reports an error of the certain test path pin.

4. The boundary scan test system according to claim 1, wherein each of the plurality of CPU test cards comprises at least one boundary scan chip disposed thereon, and when each of the plurality of CPU test card is plugged into the corresponding one of the plurality of CPU slots, the at least one boundary scan chip is connected to a plurality of ground pins, a plurality of power pins, and a plurality of control I/O pins of the corresponding CPU slot.

5. A boundary scan test method, comprising the steps:
providing a to-be-tested motherboard, a plurality of CPU test cards, and a plurality of DIMM test cards, wherein the to-be-tested motherboard comprises a plurality of CPU slots and a plurality of DIMM slots, the plurality of CPU slots are connected to each other via a plurality of QPI lines, the plurality of CPU slots are connected to the plurality of DIMM slots via a plurality of I/O lines, each of the plurality of CPU test cards comprises a plurality of first loopback lines and a plurality of second loopback lines, and each of the plurality of DIMM test cards comprises at least one boundary scan unit;
plugging the plurality of CPU test cards into the plurality of CPU slots in one-to-one correspondence, to connect two ends of each of the plurality of first loopback lines of each of the plurality of CPU test cards to one of the plurality of QPI lines and one of the plurality of I/O lines, respectively, and connect two ends of each of the plurality of second loopback lines of each of the plurality of CPU test cards to two of the plurality of I/O lines, respectively;
plugging the plurality of DIMM test cards into the plurality of DIMM slots in one-to-one correspondence, to connect the at least one boundary scan unit of each of the plurality of DIMM test cards to one of the plurality of I/O lines;
generating a plurality of boundary scan nets according to connection relationships between the plurality of CPU test cards, the plurality of DIMM test cards and the to-be-tested motherboard;
in each of the plurality of boundary scan nets, selecting and triggering one of the plurality of boundary scan units to output an excitation signal, and making the other of the plurality of boundary scan units receive corresponding response signals; and
comparing each response signal with its corresponding expectation signal in each of the plurality of boundary scan nets, to output a diagnosis result of each of the plurality of boundary scan nets.

6. The boundary scan test method according to claim 5, wherein each of the plurality of boundary scan nets comprises a plurality of test path pins, and the step of comparing the response signals with their corresponding expectation signals in each of the plurality of boundary scan nets, to output the diagnosis result of each of the plurality of boundary scan nets, comprises:
when only one of the response signals of a certain boundary scan net of the plurality of boundary scan nets mismatches its corresponding expectation signal, reporting an error of the test path pin connected to the boundary scan unit receiving the only one response signal mismatching its expectation signal, to output the diagnosis result of the certain boundary scan net;
when multiple test paths of a certain boundary scan net of the plurality of boundary scan nets pass through a certain test path pin of the plurality of test path pins, checking whether the multiple test paths through the certain test path pin pass the test;
when at least one of the multiple test paths through the certain test path pins passes the test, indicating that the certain test path pin passes the test; and
when all of the multiple test paths through the certain test path pins fail to pass the test, reporting an error of the certain test path pin.

7. The boundary scan test method according to claim 5, wherein each of the plurality of boundary scan nets comprises a plurality of test path pins, and the step of comparing the response signals with their corresponding expectation signals in each of the plurality of boundary scan nets, to output the diagnosis result of each of the plurality of boundary scan nets, comprises:
when all of the response signals of a certain boundary scan net of the plurality of boundary scan nets mismatch their corresponding expectation signals, reporting errors of all of the test path pins of the certain boundary scan net, to output the diagnosis result of the certain boundary scan net;
when multiple test paths of a certain boundary scan net of the plurality of boundary scan nets pass a certain test path pin of the plurality of test path pins, checking whether the multiple test paths through the certain test path pin pass the test;
when at least one of the multiple test paths through the certain test path pin passes the test, indicating that the certain test path pin passes the test; and
when all of the multiple test paths through the certain test path pin fail to pass the test, reporting an error of the certain test path pin.

8. The boundary scan test method according to claim 5, wherein each of the plurality of CPU test cards comprises at least one boundary scan chip disposed thereon, and when each of the plurality of CPU test cards is plugged into a corresponding one of the plurality of CPU slots, the at least one boundary scan chip is connected to a plurality of ground pins, a plurality of power pins and a plurality of control I/O pins of corresponding one of the plurality of CPU slots.
